(19) United States
(12) Patent Application Publication
(10) Pub. No.: US 2026/0188358 A1
(43) Pub. Date: Jul. 2, 2026

(54) INTERNAL VOLTAGE GENERATION CIRCUITS CONTROLLING DRIVING FORCE FOR DRIVING INTERNAL VOLTAGE

(71) Applicant: SK hynix Inc., Icheon-si Gyeonggi-do (KR)

(72) Inventors: Sang Hyun KU, Icheon-si Gyeonggi-do (KR); Cheol Hoe KIM, Icheon-si Gyeonggi-do (KR)

(73) Assignee: SK hynix Inc., Icheon-si Gyeonggi-do (KR)

(21) Appl. No.: 19/211,839

(22) Filed: May 19, 2025

(30) Foreign Application Priority Data
Dec. 30, 2024 (KR) 10-2024-0201427

(51) Int. Cl. G11C 5/14; G11C 29/50

(52) U.S. Cl. CPC G11C 5/147; G11C 29/50; G11C 2029/5004

(57) ABSTRACT

An internal voltage generation circuit includes a drive control circuit configured to generate a drive signal and an additional drive signal to control a driving force that drives an internal voltage during a refresh operation on a redundancy cell and during a refresh operation on a normal cell, and a voltage driving circuit configured to control the driving force that drives the internal voltage based on the drive signal and the additional drive signal.

### CROSS-REFERENCE TO RELATED APPLICATIONS

The present application claims priority under 35 U.S.C § 119(a) to Korean Application No. 10-2024-0201427, filed in the Korean Intellectual Property Office on Dec. 30, 2024, the entire contents of which application is incorporated herein by reference.

### BACKGROUND

### 1. Technical Field

The present disclosure relates to semiconductor memory devices internal voltage including but not limited to a refresh operation for semiconductor memory devices.

### 2. Related Art

Among memory devices, unlike an SRAM (Static Random Access Memory) device or a flash memory device, a DRAM device loses information stored in memory cells over time. To prevent such an occurrence, an operation is performed to rewrite the information stored in the memory cells at regular intervals, and this series of operations is called “refresh”. Refresh is performed by activating a word line at least once within the retention time of each memory cell in a memory cell array to sense and amplify the data. The retention time refers to the time period during which data can be retained in a memory cell without refreshing after being written in the memory cell.

Memory devices receive a power supply voltage VDD and a ground voltage VSS from outside the memory device to generate and use internal voltages for internal operations of the memory devices. The internal voltages for the internal operation of a memory device include a core voltage VCORE supplied to a memory core region, a high voltage VPP used to drive word lines or for overdriving, and a back bias voltage VBB supplied as a bulk voltage of NMOS transistors in the core region.

### SUMMARY

The present disclosure describes an internal voltage generation circuit that may include a drive control circuit configured to generate a drive signal and an additional drive signal to control a driving force that drives an internal voltage during a refresh operation on a redundancy cell and during a refresh operation on a normal cell, and a voltage driving circuit configured to control the driving force that drives the internal voltage based on the drive signal and the additional drive signal.

The present disclosure describes an internal voltage generation circuit that may include a first comparator configured to compare a feedback voltage generated by dividing an internal voltage based on a drive signal and an additional drive signal with a reference voltage and configured to generate an additional pull-up signal, a second comparator configured to compare the feedback voltage with the reference voltage based on the drive signal and configured to generate a pull-up signal, a first driving device configured to drive the internal voltage based on the additional pull-up signal, and a second driving device configured to drive the internal voltage based on the pull-up signal. Activation of the drive signal and activation of the additional drive signal may be detected during a refresh operation on the redundancy cell and during the refresh operation on the normal cell.

The present disclosure describes a method that may include generating a drive signal and an additional drive signal to control a driving force that drives an internal voltage during a refresh operation on a redundancy cell and during a refresh operation on a normal cell; controlling the driving force that drives the internal voltage based on the drive signal and the additional drive signal; and generating the drive signal as activated and the additional drive signal as deactivated when the refresh operation is performed on the redundancy cell.

### BRIEF DESCRIPTION OF THE DRAWINGS

FIG. 1 is a block diagram illustrating a memory device according to an embodiment of the present disclosure.

FIG. 2 is a block diagram illustrating a row control circuit according to an embodiment of the present disclosure.

FIG. 3 is a block diagram illustrating a memory cell array according to an embodiment of the present disclosure.

FIG. 4 is a flowchart showing a refresh operation performed in a memory device according to an embodiment of the present disclosure.

FIG. 5 is a block diagram illustrating an internal voltage generation circuit according to an embodiment of the present disclosure.

FIG. 6 is a circuit diagram illustrating a drive control circuit according to an embodiment of the present disclosure.

FIG. 7 is a circuit diagram illustrating a voltage driving circuit according to an embodiment of the present disclosure.

FIG. 8 is a timing diagram during a method of performing a refresh operation on a normal cell according to an embodiment of the present disclosure.

FIG. 9 is a block diagram illustrating a drive control circuit during a refresh operation performed on a normal cell according to an embodiment of the present disclosure.

FIG. 10 is a block diagram illustrating a voltage driving circuit during a refresh operation performed on a normal cell according to an embodiment of the present disclosure.

FIG. 11 is a timing diagram during a method of performing a refresh operation on a redundancy cell according to an embodiment of the present disclosure.

FIG. 12 is a block diagram illustrating a drive control circuit during a refresh operation performed on a redundancy cell according to an embodiment of the present disclosure.

FIG. 13 is a block diagram illustrating a voltage driving circuit during a refresh operation performed on a redundancy cell according to an embodiment of the present disclosure.

FIG. 14 is a timing diagram during a test mode according to an embodiment of the present disclosure.

FIG. 15 is a block diagram illustrating a drive control circuit during a test mode according to an embodiment of the present disclosure.

FIG. 16 is a block diagram illustrating a voltage driving circuit during a test mode according to an embodiment of the present disclosure.

### DETAILED DESCRIPTION

The present disclosure relates to internal voltage generation circuits controlling a driving force during a refresh operation. The core voltage VCORE can be supplied by reducing an externally input power supply voltage VDD to a predetermined level, although the high voltage VPP has a higher voltage level than the externally input power supply voltage VDD, and the back bias voltage VBB is maintained at a lower voltage level than the externally input ground voltage VSS. To supply the high voltage VPP and the back bias voltage VBB to the memory device, a charge pump circuit supplies the charge for the high voltage VPP and the back bias voltage VBB.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

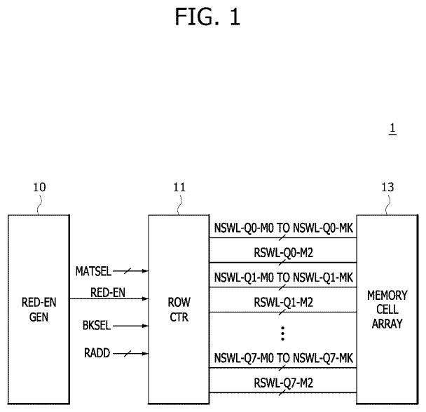

FIG. 1 is a block diagram illustrating a memory device 1 according to an embodiment of the present disclosure.

As shown in FIG. 1, the memory device 1 includes a redundancy activation signal generation circuit (RED-EN GEN) 10, a row control circuit (RDW CTR) 11, and a memory cell array (MEMORY CELL ARRAY) 13.

The redundancy activation signal generation circuit 10 generates a redundancy activation signal RED-EN including information identifying whether a repair operation is performed on memory cells included in the memory cell array 13. The redundancy activation signal generation circuit 10 generates the redundancy activation signal RED-EN as activated at a first logic level when a repair operation is performed on normal cells included in the memory cell array 13. The redundancy activation signal generation circuit 10 generates the redundancy activation signal RED-EN as deactivated at a second logic level different from the first logic level when a repair operation is performed on redundancy cells included in the memory cell array 13.

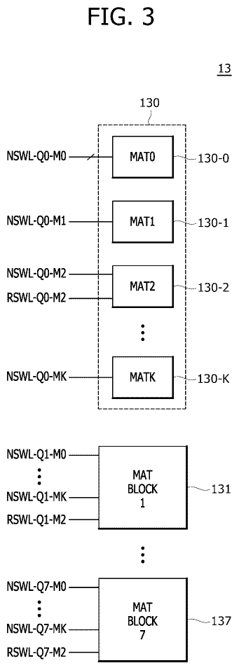

The row control circuit 11 selectively activates normal sub-word lines NSWL-Q0-M0 to NSWL-Q0-MK, NSWL-Q1-M0 to NSWL-Q1-MK, . . . , and NSWL-Q7-M0 to NSWL-Q7-MK connected to the normal cells included in the memory cell array 13, and selectively activates redundancy sub-word lines RSWL-Q0-M2, RSWL-Q1-M2, . . . , and RSWL-Q7-M2 connected to the redundancy cells included in the memory cell array 13 based on a mat selection signal MATSEL, the redundancy activation signal RED-EN, a bank selection signal BKSEL, and a row address RADD when an active operation or a refresh operation is performed. The redundancy cells refer to memory cells that replace defective normal cells utilizing a repair operation. The mat selection signal MATSEL includes information that selects one of a plurality of mat blocks, for example, components indicated by reference numerals 130 to 137 in FIG. 3, included in the memory cell array 13. For example, the mat selection signal MATSEL may include a plurality of bits of a logic bit set corresponding to each of the mat blocks. Each of the mat blocks includes normal cells connected to the normal sub-word lines NSWL-Q0-M0 to NSWL-Q0-MK, NSWL-Q1-M0 to NSWL-Q1-MK, . . . , and NSWL-Q7-M0 to NSWL-Q7-MK and redundancy cells connected to the redundancy sub-word lines RSWL-Q0-M2, RSWL-Q1-M2, . . . , and RSWL-Q7-M2 that are activated for a refresh operation during a retention time period, for example, 32 ms. The quantity of normal sub-word lines NSWL-Q0-M0 to NSWL-Q0-MK, NSWL-Q1-M0 to NSWL-Q1-MK, . . . , and NSWL-Q7-M0 to NSWL-Q7-MK and the quantity of redundancy sub-word lines RSWL-Q0-M2, RSWL-Q1-M2, . . . , and RSWL-Q7-M2 included in the mat block may be 8K, for example, 8,192 in this example, and the present disclosure is not limited to this example. The bank selection signal BKSEL includes information for selecting one of banks (not shown) included in the memory cell array 13. Each of the banks includes a plurality of mat blocks in this example, and the present disclosure is not limited to this example. The row address RADD includes information for selectively activating the normal sub-word lines NSWL-Q0-M0 to NSWL-Q0-MK, NSWL-Q1-M0 to NSWL-Q1-MK, . . . , and NSWL-Q7-M0 to NSWL-Q7-MK included in the mat block in an active operation or a refresh operation. For example, the row address RADD includes a plurality of bits of a logic bit set corresponding to each of the normal sub-word lines NSWL-Q0-M0 to NSWL-Q0-MK, NSWL-Q1-M0 to NSWL-Q1-MK, . . . , and NSWL-Q7-M0 to NSWL-Q7-MK.

When an active operation or a refresh operation is performed, the memory cell array 13 is electrically connected to the normal sub-word lines NSWL-Q0-M0 to NSWL-Q0-MK, NSWL-Q1-M0 to NSWL-Q1-MK, . . . , and NSWL-Q7-M0 to NSWL-Q7-MK and the redundancy sub-word lines RSWL-Q0-M2, RSWL-Q1-M2, . . . , and RSWL-Q7-M2 that are selectively activated by the row control circuit 11. The memory cell array 13 includes a plurality of mat blocks, and each of the plurality of mat blocks includes the normal cells connected to the normal sub-word lines NSWL-Q0-M0 to NSWL-Q0-MK, NSWL-Q1-M0 to NSWL-Q1-MK, . . . , and NSWL-Q7-M0 to NSWL-Q7-MK and the redundancy cells connected to the redundancy sub-word lines RSWL-Q0-M2, RSWL-Q1-M2, . . . , and RSWL-Q7-M2. The memory cell array 13 performs an active operation or a refresh operation on the mat blocks including the normal cells connected to the normal sub-word lines NSWL-Q0-M0 to NSWL-Q0-MK, NSWL-Q1-M0 to NSWL-Q1-MK, . . . , and NSWL-Q7-M0 to NSWL-Q7-MK while a repair operation is not performed. The memory cell array 13 performs an active operation or a refresh operation on the mat blocks including the normal cells connected to the normal sub-word lines NSWL-Q0-M0 to NSWL-Q0-MK, NSWL-Q1-M0 to NSWL-Q1-MK, . . . , and NSWL-Q7-M0 to NSWL-Q7-MK during a repair operation, and performs an active operation or a refresh operation on the mat blocks including the redundancy cells connected to the redundancy sub-word lines RSWL-Q0-M2, RSWL-Q1-M2, . . . , and RSWL-Q7-M2.

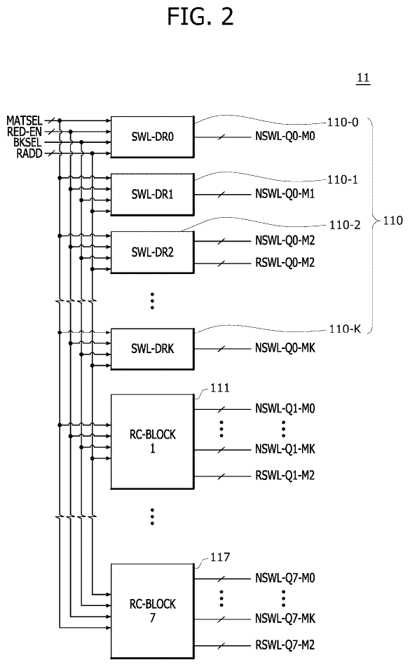

FIG. 2 is a block diagram illustrating a row control circuit 11 according to an embodiment of the present disclosure, for example, as shown in FIG. 1. As shown in FIG. 2, the row control circuit 11 includes a first row control circuit 110 to an eighth row control circuit 117.

The first row control circuit 110 selectively activates normal sub-word lines NSWL-Q0-M0 to NSWL-Q0-MK connected to normal cells included in a first mat block, for example, a component indicated by reference numeral 130 in FIG. 3 or selectively activates redundancy sub-word line RSWL-Q0-M2 connected to redundancy cells included in the first mat block, based on a mat selection signal MATSEL, a redundancy activation signal RED-EN, a bank selection signal BKSEL, and a row address RADD when an active operation or a refresh operation is performed.

The first row control circuit 110 includes a first sub-word line driver SWL-DR 0 110-0 to a K^{th} sub-word line driver SWL-DRK 110-K, where K is an integer greater than 1. The first sub-word line driver 110-0 selectively activates the normal sub-word lines NSWL-Q 0-M0 to which the normal cells included in a first mat are connected, for example, a component indicated by reference numeral 130-0 in FIG. 3 of the first mat block 130, based on the mat selection signal MATSEL, the redundancy activation signal RED-EN, the bank selection signal BKSEL, and the row address RADD when an active operation or a refresh operation is performed. When the quantity of sub-word lines included in the first mat block is 8,192, and the quantity of normal sub-word lines NSWL-Q 0-M0 is 8,192/K, although the present disclosure is not limited to this example.

The second sub-word line driver 110-1 selectively activates the normal sub-word lines NSWL-Q0-M1 to which the normal cells included in a second mat are connected, for example, a component indicated by reference numeral 130-1 in FIG. 3 of the first mat block 130, based on the mat selection signal MATSEL, the redundancy enable signal RED-EN, the bank selection signal BKSEL, and the row address RADD when the active operation or the refresh operation is performed. When the quantity of sub-word lines included in the first mat block is 8,192, and the quantity of normal sub-word lines NSWL-Q0-M1 is 8,192/K, although the present disclosure is not limited to this example.

The third sub-word line driver 110-2 selectively activates the normal sub-word lines NSWL-Q0-M2 to which the normal cells included in a third mat are connected, for example, a component indicated by reference numeral 130-2 in FIG. 3 of the first mat block 130 or selectively activates the redundancy sub-word lines RSWL-Q0-M2 connected to the redundancy cells included in the third mat of the first mat block, based on the mat selection signal MATSEL, the redundancy enable signal RED-EN, the bank selection signal BKSEL, and the row address RADD when the active operation or the refresh operation is performed. When the quantity of sub-word lines included in the first mat block is 8,192, the quantity of normal sub-word lines NSWL-Q0-M2, and the quantity of redundancy sub-word lines RSWL-Q0-M2 is 8,192/K, although the present disclosure is not limited to this example.

The (K+1) sub-word line driver 110-K selectively activates the normal sub-word lines NSWL-Q0-MK to which the normal cells included in a (K+1) mat are connected, for example, a component indicated by reference numeral 130-K in FIG. 3 of the first mat block 130, based on the mat selection signal MATSEL, the redundancy enable signal RED-EN, the bank selection signal BKSEL, and the row address RADD when the active operation or the refresh operation is performed. When the quantity of sub-word lines included in the first mat block is 8,192, and the quantity of normal sub-word lines NSWL-Q0-MK is 8,192/K, although the present disclosure is not limited to this example.

The second row control circuit 111 selectively activates normal sub-word lines NSWL-Q1-M0 to NSWL-Q1-MK connected to the normal cells included in the second mat block, for example, a component indicated by reference numeral 131 in FIG. 3, or selectively activates redundancy sub-word lines RSWL-Q1-M2 connected to the redundancy cells included in the second mat block, based on the mat selection signal MATSEL, the redundancy enable signal RED-EN, the bank selection signal BKSEL, and the row address RADD when the active operation or the refresh operation is performed. The second row control circuit 111 includes (K+1) sub-word line drivers similar to the sub-word line drivers of the first row control circuit 110 and operates in a similar manner as the first row control circuit 110 operates.

The eighth row control circuit 117 selectively activates normal sub-word lines NSWL-Q7-M0 to NSWL-Q7-MK connected to the normal cells included in an eighth mat block, for example, a component indicated by reference numeral 137 in FIG. 3, or selectively activates redundancy sub-word lines RSWL-Q7-M2 connected to the redundancy cells included in the eighth mat block, based on the mat selection signal MATSEL, the redundancy enable signal RED-EN, the bank selection signal BKSEL, and the row address RADD when the active operation or the refresh operation is performed. The eighth row control circuit 117 includes (K+1) sub-word line drivers similar to the sub-word line drivers of the first row control circuit 110 and operates in a similar manner as the first row control circuit 110. The third row control circuits 112 to the seventh row control circuit 116 (not shown) may be implemented with a similar construction as the first row control circuit 110 including (K+1) sub-word line drivers.

FIG. 3 is a block diagram illustrating a memory cell array 13 according to an embodiment of the present disclosure, for example, as shown in FIG. 1. As shown in FIG. 3, the memory cell array 13 includes first mat block 130 to eighth mat block 137.

The first mat block 130 includes a first mat 130-0 to a (K+1) mat 130-K connected to normal sub-word lines NSWL-Q0-M0 to NSWL-Q0-MK selectively activated by the first row control circuit 110 in FIG. 2, respectively, when an active operation or a refresh operation is performed. The first mat 130-0 includes a plurality of normal cells connected to activated normal sub-word lines NSWL-Q0-M0 and performs an active operation or a refresh operation. The second mat 130-1 includes a plurality of normal cells connected to activated normal sub-word lines NSWL-Q0-M1 and performs an active operation or a refresh operation. The third mat 130-2 includes a plurality of normal cells connected to activated normal sub-word lines NSWL-Q0-M2 and performs an active operation or a refresh operation. The (K+1) mat 130-K includes a plurality of normal cells connected to activated normal sub-word lines NSWL-Q0-MK and performs an active operation or a refresh operation. The first mat block 130 includes the third mat 130-2 connected to redundancy sub-word lines RSWL-Q0-M2 selectively activated by the first row control circuit 110 in FIG. 2 when an active operation or a refresh operation is performed during a repair operation. The third mat 130-2 includes a plurality of redundancy cells connected to activated redundancy sub-word lines RSWL-Q0-M2 and performs an active operation or a refresh operation.

The second mat block 131 includes a plurality of mats connected to normal sub-word lines NSWL-Q1-M0 to NSWL-Q1-MK selectively activated by the second row control circuit 111 in FIG. 2 when an active operation or a refresh operation is performed. The second mat block 131 includes a mat connected to redundancy sub-word lines RSWL-Q1-M2 selectively activated by the second row control circuit 111 when the active operation or the refresh operation is performed during a repair operation. The mats included in the second mat block 131 are implemented with a similar construction as the mats included in the first mat block 130.

The eighth mat block 137 includes a plurality of mats (not shown) connected to normal sub-word lines NSWL-Q7-M0 to NSWL-Q7-MK selectively activated by the eighth row control circuit 117 in FIG. 2 when an active operation or a refresh operation is performed. The eighth mat block 137 includes a mat connected to redundancy sub-word lines RSWL-Q7-M2 selectively activated by the eighth row control circuit 117 when the active operation or the refresh operation is performed during a repair operation. The mats included in the eighth mat block 137 are implemented in a similar manner as the mats included in the first mat block 130. The third to seventh mat blocks 132 to 136 are not shown, but may be implemented in the same manner as the first mat block 130 including (K+1) mats.

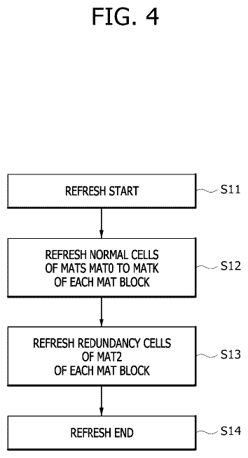

FIG. 4 is a flowchart showing a refresh operation performed in a memory device 1 according to an embodiment of the present disclosure, for example, as shown in FIG. 1 to FIG. 3. The processes of the flowchart may be performed in a different order and may include fewer or additional processes than described and shown in FIG. 4.

Referring to FIG. 2, FIG. 3, and FIG. 4, when a refresh operation is started S11 when a defect occurs in a normal cell included in the memory cell array 13 and a defective cell is replaced with a redundancy cell, for example, in the third mat MAT2, the row control circuits 110 to 117 selectively activate the normal sub-word lines NSWL-Q0-M0 to NSWL-Q0-MK. A refresh operation is performed S12 on the normal cells included in the mats MAT0 to MAT(K+1) of each of the mat blocks, such as the mat blocks 130 to 137, by selectively activating normal sub-word lines NSWL-Q0-M0 to NSWL-Q0-MK, NSWL-Q1-M0 to NSWL-Q1-MK, . . . , and NSWL-Q7-M0 to NSWL-Q7-MK.

Referring to FIG. 2, FIG. 3, and FIG. 4, the row control circuits 110 to 117 selectively activate the redundancy sub-word lines RSWL-Q0-M2, RSWL-Q1-M2, . . . , and RSWL-Q7-M2. In this example, a refresh operation is performed S13 on the redundancy cells included in the third mat MAT2 of each of the mat blocks 130 to 137 by selectively activating the redundancy sub-word lines RSWL-Q0-M2, RSWL-Q1-M2, . . . , and RSWL-Q7-M2. The refresh operation on the redundancy cells may be performed after performing a refresh operation on the normal cells.

After the refresh operations on the normal cells and redundancy cells included in each of the mat blocks 130 to 137 are performed, the refresh operation is terminated S14.

As described, when a refresh operation is performed in the memory device 1 during a repair operation, a refresh operation is performed on the normal cells included in the mats MAT0 to MAT(K+1) of each of the mat blocks 130 to 137, and a refresh operation is performed on the redundancy cells included in the third mat MAT2 of each of the mat blocks 130 to 137. Because the refresh operation on the normal cells is performed simultaneously for the (K+1) mats and the refresh operation on the redundancy cells is performed for one mat, when the driving force used to drive an internal voltage VCORE when refreshing the redundancy cells is not reduced or lower compared to the driving force used to drive the internal voltage when refreshing the normal cells, an overshoot occurs when the internal voltage VCORE is excessively driven. The memory device 1 can prevent or reduce overshoot by reducing the driving force used to drive the internal voltage VCORE when refreshing the redundancy cells compared to the driving force for driving the internal voltage when refreshing the normal cells. During a test mode of the memory device 1, the function of reducing the driving force for the internal voltage VCORE can be blocked during the refresh operation on the redundancy cells, facilitating free or variable control of the driving force that drives the internal voltage.

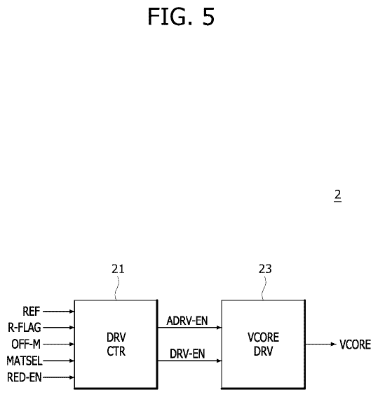

FIG. 5 is a block diagram illustrating an internal voltage generation circuit 2 according to an embodiment of the present disclosure.

As shown in FIG. 5, the internal voltage generation circuit 2 includes a drive control circuit (DRV CTR) 21 and a voltage driving circuit (VCORE DRV) 23.

The drive control circuit 21 generates a drive signal DRV-EN and an additional drive signal ADRV-EN based on a refresh signal REF, a redundancy flag signal R-FLAG, an off-mode signal OFF-M, a mat selection signal MATSEL, and a redundancy activation signal RED-EN. The refresh signal REF is activated during a refresh operation. The redundancy flag signal R-FLAG is activated when a refresh operation is performed on redundancy cells. The off-mode signal OFF-M is activated during a test mode while control of the driving force for the internal voltage VCORE is stopped during a refresh operation. When a refresh operation is performed on normal cells included in a mat selected by the mat selection signal MATSEL, the drive control circuit 21 receives an activated refresh signal REF and a deactivated redundancy flag signal R-FLAG to generate the drive signal DRV-EN as activated and the additional drive signal ADRV-EN as activated. When the refresh operation is performed on the normal cells, the drive control circuit 21 generates the activated drive signal DRV-EN and the activated additional drive signal ADRV-EN to drive the internal voltage VCORE with a first driving force. When a refresh operation is performed on redundancy cells included in a mat selected by the mat selection signal MATSEL, the drive control circuit 21 receives an activated refresh signal REF, an activated redundancy flag signal R-FLAG, and a deactivated off-mode signal OFF-M to generate an activated drive signal DRV-EN and a deactivated additional drive signal ADRV-EN. When the refresh operation is performed on the redundancy cells, the drive control circuit 21 generates the activated drive signal DRV-EN and the deactivated additional drive signal ADRV-EN to drive the internal voltage VCORE with a second driving force. The second driving force is smaller than the first driving force to prevent the internal voltage VCORE from overshooting or spiking. When the refresh operation is performed on the redundancy cells during the test mode when the activated off-mode signal OFF-M is received, the drive control circuit 21 generates the activated drive signal DRV-EN and the activated additional drive signal ADRV-EN. Accordingly, the internal voltage VCORE is controlled to drive with the first driving force in a similar manner as when the refresh operation is performed on the normal cells.

The voltage driving circuit 23 is electrically connected to the drive control circuit 21 and receives the drive signal DRV-EN and the additional drive signal ADRV-EN from the drive control circuit 21. The voltage driving circuit 23 drives the internal voltage VCORE with a driving force based on the drive signal DRV-EN and the additional drive signal ADRV-EN. The voltage driving circuit 23 drives the internal voltage VCORE with the driving force based on the drive signal DRV-EN and the additional drive signal ADRV-EN when the internal voltage VCORE falls to a preset voltage level or less. When a refresh operation is performed on the normal cells and an activated drive signal DRV-EN and an activated additional drive signal ADRV-EN are received, the voltage drive circuit 23 drives the internal voltage VCORE using a first driving force. When a refresh operation is performed on the redundancy cells and the activated drive signal DRV-EN and a deactivated additional drive signal ADRV-EN are received, the voltage driving circuit 23 drives the internal voltage VCORE with a second driving force. During the test mode when an activated off-mode signal OFF-M is received, when the refresh operation is performed on the redundancy cells and the activated drive signal DRV-EN and the activated additional drive signal ADRV-EN are received, the voltage driving circuit 23 drives the internal voltage VCORE with the first driving force. In an embodiment, the memory device 1 provides the test mode that can disable the function of reducing the driving force of the internal voltage VCORE during a refresh operation for the redundancy cells, thereby allowing flexible control over whether or not to adjust the driving force that drives the internal voltage VCORE.

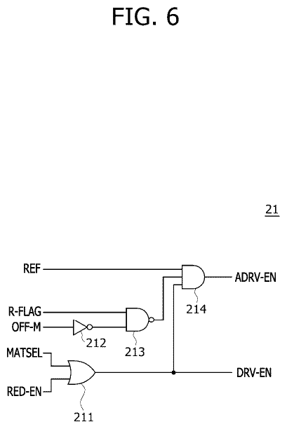

FIG. 6 is a circuit diagram illustrating a drive control circuit 21 according to an embodiment of the present disclosure, for example, as shown in FIG. 5.

As shown in FIG. 6, the drive control circuit 21 includes an OR gate 211, an inverter 212, a NAND gate 213, and an AND gate 214. The OR gate 211 receives a mat selection signal MATSEL and a redundancy enable signal RED-EN and performs a logical OR operation on the mat selection signal MATSEL and the redundancy enable signal RED-EN. The OR gate 211 receives the mat selection signal MATSEL activated at a logic high level to output a drive signal DRV-EN activated at a logic high level when a mat on which a refresh operation is to be performed is selected. The OR gate 211 receives the mat selection signal MATSEL activated at a logic high level to output the drive signal DRV-EN activated at a logic high level during a repair operation. The inverter 212 inversely buffers an off-mode signal OFF-M to output an inversely buffered off-mode signal OFF-M. While the test mode that stops control of the driving force for the internal voltage VCORE is not performed, and the off-mode signal OFF-M is received deactivated at a logic low level, the inverter 212 outputs a signal at a logic high level. While the test mode that stops control of the driving force for the internal voltage VCORE is performed and the off-mode signal OFF-M activated at a logic high level is received, the inverter 212 outputs a signal at a logic low level. The NAND gate 213 receives a redundancy flag signal R-FLAG and an output signal of the inverter 212 to perform a logical NAND operation. When a refresh operation is performed on the normal cells and the redundancy flag signal R-FLAG is received deactivated at a logic low level while test mode is not performed and the off-mode signal OFF-M is received deactivated at a logic low level, the NAND gate 213 outputs a signal at a logic high level. When the refresh operation is performed on the redundancy cells and the redundancy flag signal R-FLAG is received activated at a logic high level while the test mode is not performed and the off-mode signal OFF-M is received deactivated at a logic low level, the NAND gate 213 outputs a signal at a logic low level. The NAND gate 213 outputs a signal at a logic high level during the test mode when the off-mode signal OFF-M is received activated at a logic high level. The AND gate 214 receives the refresh signal REF, an output signal of the NAND gate 213, and the drive signal DRV-EN to perform a logical AND operation and output the additional drive signal ADRV-EN. When a refresh operation is performed on the normal cells included in a mat selected by the mat selection signal MATSEL and the redundancy flag signal R-FLAG is received deactivated at a logic low level while the test mode is not performed and the off-mode signal OFF-M is received deactivated at a logic low level, the AND gate 214 outputs the additional drive signal ADRV-EN activated at a logic high level. When a refresh operation is performed on the redundancy cells included in the mat selected by the mat selection signal MATSEL and the redundancy flag signal R-FLAG is received activated at a logic high level while the test mode is not performed and the off-mode signal OFF-M is received deactivated at a logic low level, the AND gate 214 outputs the additional drive signal ADRV-EN deactivated at a logic low level. During the test mode, when the off-mode signal OFF-M is received activated at a logic high level, and a refresh operation is performed, the AND gate 214 outputs the additional drive signal ADRV-EN activated at a logic high level.

When a refresh operation is performed on the normal cells included in the mat selected by the mat selection signal MATSEL and the redundancy flag signal R-FLAG is received deactivated at a logic low level while test mode is not performed and the off-mode signal OFF-M is received deactivated at a logic low level, the OR gate 211 of the drive control circuit 21 outputs the drive signal DRV_EN activated at a logic high level, and the AND gate 214 outputs the additional drive signal ADRV-EN activated at a logic high level.

When a refresh operation is performed on the redundancy cells included in the mat selected by the mat selection signal MATSEL and the redundancy flag signal R-FLAG is received activated at a logic high level while the test mode is not performed and the off-mode signal OFF-M is received deactivated at a logic low level, the OR gate 211 of the drive control circuit 21 outputs the drive signal DRV_EN activated at a logic high level, and the AND gate 214 outputs the additional drive signal ADRV-EN deactivated at a logic low level.

When the test mode is performed and the off-mode signal OFF-M is received activated at a logic high level, the OR gate 211 of the drive control circuit 21 outputs the drive signal DRV_EN activated at a logic high level, and the AND gate 214 outputs the additional drive signal ADRV-EN deactivated at a logic low level.

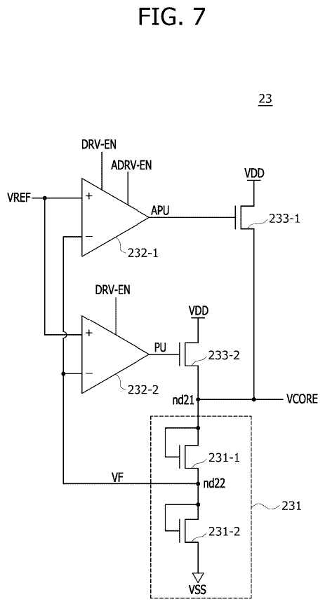

FIG. 7 is a circuit diagram illustrating a voltage driving circuit 23 according to an embodiment of the present disclosure, for example, as shown in FIG. 5.

As shown in FIG. 7, the voltage driving circuit 23 includes a voltage division circuit 231, a first comparator 232-1, a second comparator 232-2, a first driving device 233-1, and a second driving device 233-2. The voltage division circuit 231 includes NMOS transistors 231-1 and 231-2 and divides an internal voltage VCORE at node nd21 to generate a feedback voltage VF at node nd22. Each of the NMOS transistors 231-1 and 231-2 operates as a resistor element. The first comparator 232-1 compares the feedback voltage VF with the internal voltage VCORE based on a drive signal DRV-EN and an additional drive signal ADRV-EN to generate an additional pull-up signal APU to drive the internal voltage VCORE. The first comparator 232-1 generates the additional pull-up signal APU activated at a logic high level to drive the internal voltage VCORE when both the drive signal DRV-EN and the additional drive signal ADRV-EN are activated at a logic high level, and the feedback voltage VF is at a voltage level lower than the internal voltage VCORE. The first driving device 233-1 is implemented with an NMOS transistor and operates as a driving device that drives the internal voltage VCORE based on the additional pull-up signal APU. The first comparator 232-1 pull-up drives the internal voltage VCORE to a power supply voltage VDD when the additional pull-up signal APU is activated at a logic high level. The second comparator 232-2 generates a pull-up signal PU activated at a logic high level to drive the internal voltage VCORE when the drive signal DRV-EN is activated at a logic high level, and the feedback voltage VF is at a voltage level lower than the internal voltage VCORE. The second driving device 233-2 is implemented with an NMOS transistor and operates as a driving device that drives the internal voltage VCORE based on the pull-up signal PU. The second driving device 233-2 pull-up drives the internal voltage VCORE to the power supply voltage VDD when the pull-up signal PU is activated at a logic high level.

When a refresh operation is performed on normal cells and the additional drive signal ADRV-EN and the drive signal DRV-EN both activated at a logic high level are received, the voltage driving circuit 23 generates the additional pull-up signal APU activated at a logic high level and the pull-up signal PU activated at a logic high level and pull-up drives the internal voltage VCORE with a first driving force based on the additional pull-up signal APU and the pull-up signal PU. The first comparator 232-1 is activated when the additional drive signal ADRV-EN is received activated at a logic high level, and the drive signal DRV-EN is received activated at a logic high level and generates the additional pull-up signal APU activated at a logic high level when the feedback voltage VF is at a voltage level lower than the internal voltage VCORE. The second comparator 232-2 is activated when the drive signal ADRV-EN is received activated at a logic high level and generates the pull-up signal PU activated at a logic high level when the feedback voltage VF is at a voltage level lower than the internal voltage VCORE. The first driving device 233-1 receives the additional pull-up signal APU activated at a logic high level to pull-up drive the internal voltage VCORE to the power supply voltage VDD, and the second driving device 233-2 receives the pull-up signal PU activated at a logic high level to pull-up drive the internal voltage VCORE to the power supply voltage VDD. Pull-up driving the internal voltage VCORE to the power supply voltage VDD by both the first drive device 233-1 and the second drive device 233-2 includes driving the internal voltage VCORE with the first driving force.

During a refresh operation on the redundancy cells, when the additional drive signal ADRV-EN is received deactivated at a logic low level, and the drive signal DRV-EN is received activated at a logic high level, the voltage driving circuit 23 generates the additional pull-up signal APU deactivated at a logic low level and the pull-up signal activated at a logic high level and pull-up drives the internal voltage VCORE with a second driving force based on the pull-up signal PU. The first comparator 232-1 is deactivated when the additional drive signal ADRV-EN is received deactivated at a logic low level and generates the additional pull-up signal APU deactivated at a logic low level to stop driving the internal voltage VCORE. The second comparator 232-2 is activated when the drive signal DRV-EN is received activated at a logic high level and generates the pull-up signal PU activated at a logic high level when the feedback voltage VF is at a lower voltage level than the internal voltage VCORE. The first driving device 233-1 is turned off in response to receiving the additional pull-up signal APU deactivated at a logic low level, and the second driving device 233-2 receives the pull-up signal PU activated at a logic high level to pull-up drive the internal voltage VCORE to the power supply voltage VDD. Pull-up driving the internal voltage VCORE to the power supply voltage VDD by the second driving device 233-2 includes driving the internal voltage VCORE with a second driving force.

During the test mode, when the additional drive signal ADRV-EN is received activated at a logic high level, and the drive signal DRV-EN is received activated at a logic high level, the voltage driving circuit 23 generates the additional pull-up signal APU activated at a logic high level and the pull-up signal PU activated at a logic high level and pull-up drives the internal voltage VCORE with the first driving force based on the additional pull-up signal APU and the pull-up signal PU. The first comparator 232-1 is activated when the drive signal DRV-EN is received activated at a logic high level, and the additional drive signal ADRV-EN is received activated at a logic high level, and generates the additional pull-up signal APU activated at a logic high level when the feedback voltage VF is at a voltage level lower than the internal voltage VCORE. The second comparator 232-2 is activated when the drive signal DRV-EN activated is received at a logic high level and generates the pull-up signal PU activated at a logic high level when the feedback voltage VF is at a voltage level lower than the internal voltage VCORE. The first driving device 233-1 receives the additional pull-up signal APU activated at a logic high level to pull-up drive the internal voltage VCORE to the power supply voltage VDD, and the second driving device 233-2 receives the pull-up signal PU activated at a logic high level to pull-up drive the internal voltage VCORE to the power supply voltage VDD.

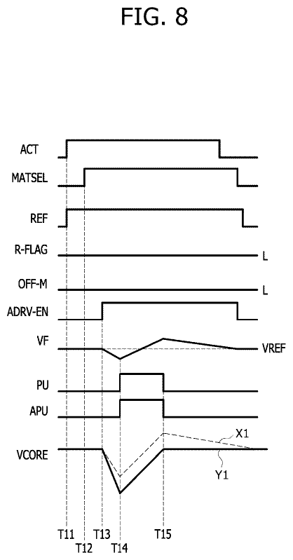

FIG. 8 to FIG. 10 illustrate operation of driving an internal voltage when a refresh operation is performed on normal cells in an internal voltage generation circuit according to an embodiment of the present disclosure, for example, as shown in FIG. 5 to FIG. 7.

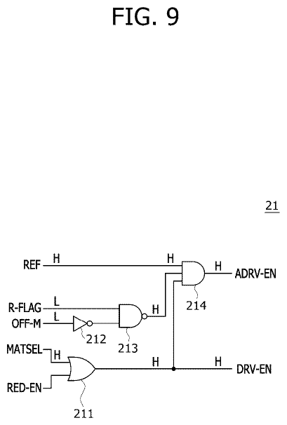

As shown in FIG. 8 and FIG. 9, when the refresh operation is performed on the normal cells while the test mode is not performed, a drive control circuit 21 receives an off-mode signal OFF-M deactivated at a logic low level L and receives an active signal ACT and a refresh signal REF activated at a logic high level H at time T11 and receives a mat selection signal MATSEL activated at a logic high level H and a redundancy flag signal R-FLAG deactivated at a logic low level L to select a mat on which a refresh is to be performed at time T12. At time T13, a drive signal DRV-EN activated at a logic high level H is output by the OR gate 211 and a signal at a logic high level H is output by the NAND gate 213, thus, the drive control circuit 21 outputs an additional drive signal ADRV-EN activated at a logic high level H by the AND gate 214.

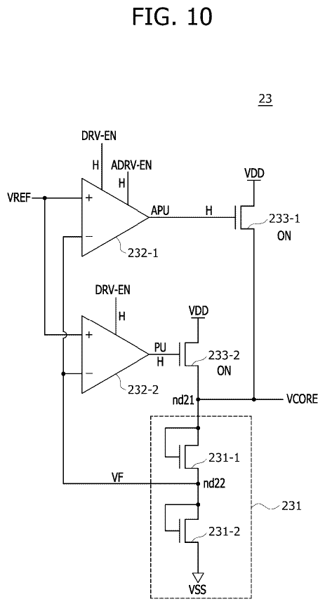

As shown in FIG. 8 and FIG. 10, during a time period T13 to T14, when a voltage level of a feedback voltage VF is lower than the reference voltage VREF at time T14, a voltage driving circuit 23 generates an additional pull-up signal APU activated at a logic high level H by the first comparator 232-1 and generates a pull-up signal PU activated at a logic high level H by the second comparator 232-2. During a time period T14 to T15, the voltage driving circuit 23 pull-up drives an internal voltage VCORE with a first driving force by the first driving device 233-1 that is turned on ON by the additional pull-up signal APU and a second driving device 233-2 that is turned on ON by the pull-up signal PU. When the refresh operation is performed on the normal cells included in one mat, a voltage level X1 of the internal voltage VCORE is maintained higher than a voltage level Y1 while the refresh operation is performed on the normal cells included in multiple mats. The voltage drop of the internal voltage VCORE during the refresh operation for the normal cells included in the multiple mats is greater than the voltage drop of the internal voltage VCORE during the refresh operation for the normal cells included in one mat.

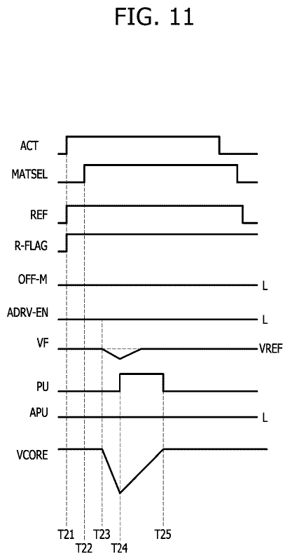

FIG. 11 to FIG. 13 illustrate operation of driving an internal voltage when a refresh operation is performed on redundancy cells in an internal voltage generation circuit according to an embodiment of the present disclosure, for example, as shown in FIG. 5 to FIG. 7.

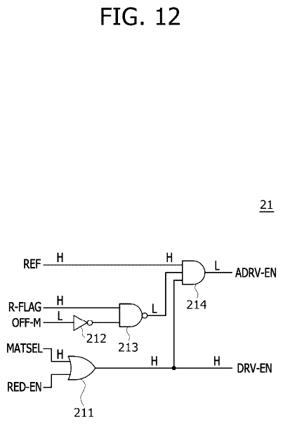

As shown in FIG. 11 and FIG. 12, when the refresh operation is performed on the redundancy cells while the test mode is not performed, a drive control circuit 21 receives an off-mode signal OFF-M deactivated at a logic low level L and receives an active signal ACT activated at a logic high level H and a refresh signal REF activated at a logic high level H at time T21, and receives a mat selection signal MATSEL activated at a logic high level H and a redundancy flag signal R-FLAG activated at a logic high level H to select a mat on which a refresh operation is to be performed at time T22. A drive signal DRV-EN activated at a logic high level H is output by the OR gate 211 and a signal at a logic low level L is output by the NAND gate 213, thus, the drive control circuit 21 outputs an additional drive signal ADRV-EN deactivated at a logic low level L by the AND gate 214.

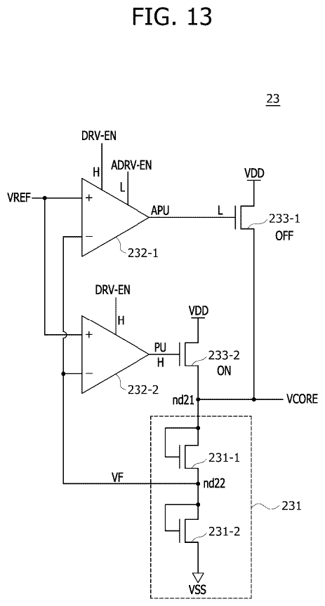

As shown in FIG. 11 and FIG. 13, when the voltage level of the feedback voltage VF is lower than the reference voltage VREF at time T24, the voltage driving circuit 23 generates an additional pull-up signal APU deactivated at a logic low level L by the first comparator 232-1 and generates a pull-up signal PU activated at a logic high level H by the second comparator 232-2. During a time period T24 to T 25, the voltage driving circuit 23 pull-up drives an internal voltage VCORE with a second driving force by the first driving device 233-1 that is turned off OFF by the additional pull-up signal APU and the second driving device 233-2 that is turned on ON by the pull-up signal PU. Because the quantity of redundancy cells is smaller than the quantity of normal cells, when a refresh operation is performed on the redundancy cells, the internal voltage VCORE is driven with a driving force smaller than a driving force when a refresh operation is performed on the normal cells, thereby preventing overshoot from occurring due to excessively driving the internal voltage VCORE.

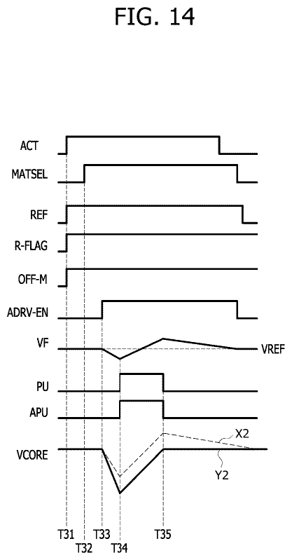

FIG. 14 to FIG. 16 illustrate a test mode during which a driving force for driving an internal voltage is blocked from being controlled in an internal voltage generation circuit 2 according to an embodiment of the present disclosure, for example, as shown in FIG. 5 to FIG. 7.

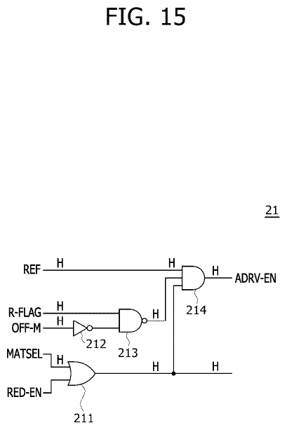

As shown in FIG. 14 and FIG. 15, when a refresh operation is performed on redundancy cells while the test mode is performed, a drive control circuit 21 receives an off-mode signal OFF-M activated at a logic high level H and receives an active signal ACT activated at a logic high level H and a refresh signal REF activated at a logic high level H at time T31, and receives a mat select signal MATSEL activated at a logic high level H and a redundancy flag signal R-FLAG activated at a logic high level H to select a mat on which a refresh is to be performed at time T32. At time T33, a drive signal DRV-EN activated at a logic high level H is output by the OR gate 211 and a signal at a logic high level H is output by the NAND gate 213, thus, the drive control circuit 21 outputs an additional drive signal ADRV-EN activated at a logic high level H by the AND gate 214.

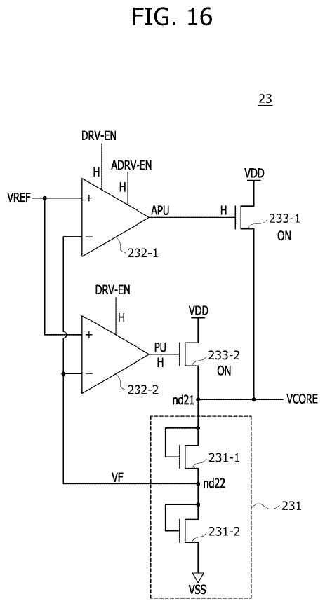

As shown in FIG. 14 and FIG. 16, during a time period T33 to T34 when the voltage level of the feedback voltage VF is lower than the reference voltage VREF at time T34, a voltage driving circuit 23 generates an additional pull-up signal APU activated at a logic high level H by the first comparator 232-1 and generates a pull-up signal PU activated at a logic high level H by the second comparator 232-2. During a time period T34 to T35, the voltage driving circuit 23 pull-up drives the internal voltage VCORE with a first driving force by the first driving device 233-1 that is turned on ON by the additional pull-up signal APU and the second driving device 233-2 that is turned on ON by the pull-up signal PU. A voltage level X2 of the internal voltage VCORE when the refresh operation is performed on the normal cells included in one mat is maintained higher than a voltage level Y2 when the refresh operation is performed on the normal cells included in multiple mats. Even when a refresh operation is performed on the redundancy cells, while the test mode is performed, the driving force that drives the internal voltage VCORE can be blocked from being controlled between the first driving force and the second driving force.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. An internal voltage generation circuit comprising:
a drive control circuit configured to generate a drive signal and an additional drive signal to control a driving force that drives an internal voltage during a refresh operation on a redundancy cell and during a refresh operation on a normal cell; and
a voltage driving circuit configured to control the driving force that drives the internal voltage based on the drive signal and the additional drive signal.

2. The internal voltage generation circuit of claim 1, wherein when the refresh operation is performed on the normal cell, the drive control circuit generates the drive signal as activated and the additional drive signal as activated.

3. The internal voltage generation circuit of claim 2, wherein the voltage driving circuit comprises:
a first driving device configured to drive the internal voltage when the drive signal is activated; and
a second driving device configured to drive the internal voltage when the additional drive signal is activated.

4. The internal voltage generation circuit of claim 1, wherein when the refresh operation is performed on the redundancy cell, the drive control circuit generates the drive signal as activated and the additional drive signal as deactivated.

5. The internal voltage generation circuit of claim 4, wherein the voltage driving circuit comprises:
a first driving device configured to drive the internal voltage when the drive signal is activated; and
a second driving device configured to stop driving the internal voltage when the additional drive signal is deactivated.

6. The internal voltage generation circuit of claim 1, wherein when the refresh operation is performed on the redundancy cell during a test mode, the drive control circuit generates the drive signal as activated and the additional drive signal as activated.

7. The internal voltage generation circuit of claim 6, wherein the voltage driving circuit comprises:
a first driving device configured to drive the internal voltage when the drive signal is activated; and
a second driving device configured to drive the internal voltage when the additional drive signal is activated.

8. The internal voltage generation circuit of claim 1, further comprising a redundancy activation signal generation circuit configured to generate a redundancy activation signal including information identifying whether a repair operation is performed on memory cells.

9. The internal voltage generation circuit of claim 1,
wherein the drive control circuit generates the drive signal and the additional drive signal based on a refresh signal, a redundancy flag signal, an off-mode signal, and a mat selection signal; and
wherein, when the refresh operation is performed on the normal cell, the drive control circuit receives the refresh signal as activated and the mat selection signal as activated, receives the redundancy flag signal as deactivated and the off-mode signal as deactivated, and generates the drive signal as activated and the additional drive signal as activated.

10. The internal voltage generation circuit of claim 9, wherein, when a refresh operation is performed on the redundancy cell, the drive control circuit receives the refresh signal as activated, the redundancy flag signal as activated, and the mat selection signal as activated, receives the off-mode signal as deactivated, and generates the drive signal as activated and the additional drive signal as deactivated.

11. The internal voltage generation circuit of claim 9, wherein when a refresh operation is performed on the redundancy cell during a test mode, the drive control circuit receives the refresh signal as activated, the redundancy flag signal as activated, the off-mode signal as activated, and the mat selection signal as activated, and generates the drive signal as activated and the additional drive signal as activated.

12. The internal voltage generation circuit of claim 1, wherein the voltage driving circuit comprises:
a voltage division circuit configured to divide the internal voltage to generate a feedback voltage;
a first comparator configured to compare the feedback voltage with the reference voltage based on the drive signal and the additional drive signal and configured to generate an additional pull-up signal;
a second comparator configured to compare the feedback voltage with the reference voltage based on the drive signal and configured to generate a pull-up signal;
a first driving device configured to drive the internal voltage based on the additional pull-up signal; and
a second driving device configured to drive the internal voltage based on the pull-up signal.

13. The internal voltage generation circuit of claim 1, wherein the first comparator and the first driving device are activated when a refresh operation is performed on the normal cell and when a refresh operation is performed on the redundancy cell during a test mode.

14. The internal voltage generation circuit of claim 1, wherein the first comparator and the first driving device are deactivated when a refresh operation is performed on the redundancy cell.

15. An internal voltage generation circuit comprising:
a first comparator configured to compare a feedback voltage generated by dividing an internal voltage based on a drive signal and an additional drive signal with a reference voltage and configured to generate an additional pull-up signal;
a second comparator configured to compare the feedback voltage with the reference voltage based on the drive signal and configured to generate a pull-up signal;
a first driving device configured to drive the internal voltage based on the additional pull-up signal; and
a second driving device configured to drive the internal voltage based on the pull-up signal;
wherein activation of the drive signal and activation of the additional drive signal is detected during a refresh operation on the redundancy cell and during the refresh operation on the normal cell.

16. The internal voltage generation circuit of claim 15, further comprising a drive control circuit configured to generate the drive signal and the additional drive signal for the refresh operation on the normal cell, the refresh operation on the normal cell, and the refresh operation on the redundancy cell during a test mode.

17. The internal voltage generation circuit of claim 16, wherein the drive control circuit generates the drive signal as activated and the additional drive signal as activated when the refresh operation is performed on the normal cell and when the refresh operation is performed on the redundancy cell during the test mode.

18. The internal voltage generation circuit of claim 16, wherein the drive control circuit generates the drive signal as activated and the additional drive signal as deactivated when the refresh operation is performed on the redundancy cell.

19. The internal voltage generation circuit of claim 16, wherein the drive control circuit generates the drive signal and the additional drive signal based on a refresh signal, a redundancy flag signal, an off-mode signal, and a mat selection signal.

20. The internal voltage generation circuit of claim 15, wherein the first comparator and the first driving device are activated when a refresh operation is performed on the normal cell and when a refresh operation is performed on the redundancy cell during a test mode and are deactivated when the refresh operation is performed on the redundancy cell.

21. A method comprising:
generating a drive signal and an additional drive signal to control a driving force that drives an internal voltage during a refresh operation on a redundancy cell and during a refresh operation on a normal cell;
controlling the driving force that drives the internal voltage based on the drive signal and the additional drive signal; and
generating the drive signal as activated and the additional drive signal as deactivated when the refresh operation is performed on the redundancy cell.
